(19) United States
(12) Patent Application Publication
(10) Pub. No.: US 2022/0310865 A1
(43) Pub. Date: Sep. 29, 2022

(54) LAMINATED CELL STRUCTURE AND PREPARATION METHOD THEREOF

(71) Applicant: SUZHOU TALESUN SOLAR TECHNOLOGIES CO., LTD., Changshu, Jiangsu (CN)

(72) Inventors: Shude ZHANG, Changshu, Jiangsu (CN); Baoxing ZHAO, Changshu, Jiangsu (CN); Zhichun NI, Changshu, Jiangsu (CN); Qingzhu WEI, Changshu, Jiangsu (CN); Weifei LIAN, Changshu, Jiangsu (CN); Xin FU, Changshu, Jiangsu (CN)

(73) Assignee: SUZHOU TALESUN SOLAR TECHNOLOGIES CO., LTD., Changshu, Jiangsu (CN)

(21) Appl. No.: 17/430,887

(22) PCT Filed: Apr. 23, 2021
(86) PCT No.: PCT/CN2021/089363

§ 371 Date: Aug. 13, 2021

(30) Foreign Application Priority Data
Sep. 23, 2020 (CN) 202011019966.1

(51) Int. Cl. H01L 31/078; H01L 31/0216; H01L 31/0236; H01L 31/18

(52) U.S. Cl. CPC H01L 31/078; H01L 31/02167; H01L 31/0236; H01L 31/18

(57) ABSTRACT

The invention discloses a laminated cell structure, the laminated cell structure comprising a top cell unit, a bottom cell unit, and an intermediate layer located between the top cell unit and the bottom cell unit; the intermediate layer being configured as a tunnel junction composed of a p⁺/n⁺ double-layer silicon thin film; the top cell unit comprising an electron transport layer, a perovskite photosensitive layer, a hole transport layer sequentially laminated in the direction from the distance to the vicinity with respect to the intermediate layer, and a front electrode provided on the electron transport layer; and the bottom cell unit being a PERC solar cell. The invention also correspondingly discloses a preparation method for the laminated cell structure. According to the invention, good perovskite cell performance can be obtained by adopting a silicon thin film tunnel junction structure. The laminated cell with the structure has high photoelectric conversion efficiency.

### CROSS-REFERENCE TO RELATED APPLICATIONS

This application is a U.S. National Stage Entry under 35 U.S.C. § 371 of International Patent Application No. PCT/CN2021/089363, entitled “LAMINATED CELL STRUCTURE AND PREPARATION METHOD THEREOF,” filed Apr. 23, 2021, which claims benefit of Chinese Application No. 202011019966.1, filed Sep. 23, 2020, the entire disclosures of which are hereby incorporated by reference herein.

### FIELD OF THE PRESENT DISCLOSURE

The invention relates to the technical field of the solar cell, in particular to a laminated cell structure and a preparation method thereof.

### BACKGROUND OF THE PRESENT DISCLOSURE

The solar cell is a semiconductor device that directly converts solar luminous energy into electric energy. By utilizing the renewable resource of luminous energy, it provides a wide development prospect for the solar cell under the circumstance of current energy shortage.

At present, in the solar cell industry, the mass production efficiency of a Passivated Emitter and Rear Cell (PERC), a Heterojunction with Intrinsic Thin film (HIT), and a Tunnel Oxide Passivated Contact (TOPCon) is continuously improved, gradually approaching the conversion efficiency limit, and the laminated solar cell is an effective means for further greatly improving the conversion efficiency of the cell. The principle of the laminated solar cell is that cells with different photovoltaic responses are integrated by various means, and the two-terminal (2T) laminated cell has better application prospects in the laminated solar cell structure. Among various laminated cells, CIGS thin film cell and silicon thin film cell are expensive and cannot be directly compatible with the industrial mass production cell structure. Although the Heterojunction with Intrinsic Thin film and perovskite cell have been reported to constitute a laminated solar cell, the highest-yield cell structure in the industry is a PERC cell at present, while two-terminal laminated solar cell composed of the PERC cell and the perovskite cell is rarely reported. In addition, due to the process characteristics of the preparation of the perovskite cell, in most reported laminated cells, the preparation of the perovskite cell is based on the bottom cell with a planar structure. The planar structure greatly improves the reflectivity of the cell so that the conversion efficiency of the bottom cell is dramatically decreased, and the photoelectric conversion performance of the cell cannot be fully effected.

### SUMMARY OF THE PRESENT DISCLOSURE

In order to solve the problems of the prior art, the invention provides a laminated cell structure and a preparation method thereof.

In one aspect, the application provides a laminated cell structure including a top cell unit, a bottom cell unit, and an intermediate layer unit arranged between the top cell unit and the bottom cell unit.

The top cell unit comprises an electron transport layer, a perovskite photosensitive layer, a hole transport layer and a front electrode;

the electron transport layer, the perovskite photosensitive layer and the hole transport layer are sequentially laminated in a direction from the distance to the vicinity with respect to the intermediate layer unit, and the hole transport layer is connected with the intermediate layer unit;

the front electrode is arranged on the electron transport layer;

the bottom cell unit comprises a passivated contact layer, a silicon oxide layer, a monocrystalline silicon base layer, a rear passivated film layer, a rear protective layer, and a rear electrode sequentially laminated in a direction from the vicinity to the distance with respect to the intermediate layer;

the passivated contact layer, the silicon oxide layer, the monocrystalline silicon base layer, the rear passivated film layer and the rear protective layer are sequentially laminated in the direction from the vicinity to the distance with respect to the intermediate layer unit, and the passivated contact layer is connected with the intermediate layer unit;

the rear electrode is arranged on the rear protective layer;

the intermediate layer unit includes a p⁺ silicon thin film layer and an n⁺ silicon thin film layer, and is configured as a tunnel junction composed of the p⁺ silicon thin film layer and the n⁺ silicon thin film layer.

The top cell unit further includes an antireflective layer, a transparent conductive layer, and a passivated protective film layer arranged on the electron transport layer, and the antireflective layer, the transparent conductive layer, and the passivated protective film layer are sequentially laminated in the direction from the distance to the vicinity with respect to the electron transport layer.

The hole transport layer is a nickel oxide layer; the electron transport layer is a zinc oxide layer or a lithium fluoride layer.

The passivated contact layer of the bottom cell unit is an n-layer silicon thin film passivated contact layer configured as a textured structure.

The passivated contact layer is formed with an inscribed electrode on its surface facing the intermediate layer unit.

In another aspect, the application provides a preparation method for the laminated cell structure, which includes the following steps:

preparing a bottom cell unit;

preparing an intermediate layer unit on the bottom cell unit; the intermediate layer unit being configured as a tunnel junction composed of a p⁺ silicon thin film layer and an n⁺ silicon thin film layer;

and preparing a top cell unit with a perovskite photosensitive layer on the intermediate layer unit.

Preparing a bottom cell unit specifically includes the following steps:

preparing a textured surface on a front and a back sides of a monocrystalline silicon wafer by using an alkaline solution;

respectively forming a first silicon oxide layer and a second silicon oxide layer on the front textured surface and the back textured surface of the monocrystalline silicon wafer;

oxidizing and annealing the second silicon oxide layer, and depositing aluminum oxide on the second silicon oxide layer to form a rear passivated film layer;

depositing a rear protective layer on the rear passivated film layer,

arranging a rear electrode on the rear passivated film layer;

depositing a passivated contact layer on the first silicon oxide layer;

respectively forming a first silicon oxide layer and a second silicon oxide layer on the front textured surface and the back textured surface of the monocrystalline silicon wafer specifically comprising the following steps:

performing phosphorus diffusion on a front textured surface of the monocrystalline silicon wafer to obtain a front textured surface formed with an n-type emitter region;

etching and polishing a rear textured surface of the monocrystalline silicon wafer to obtain a rear textured surface with a rear diffusion layer and a side face conductive channel removed;

and performing thermal oxidation on the monocrystalline silicon wafer in an oxidation furnace, and respectively forming a first silicon oxide layer and a second silicon oxide layer on the front textured surface and the back textured surface of the monocrystalline silicon wafer.

The front side is cleaned; the front side is oxidized, and a thin oxide layer of 1-10 nm is formed on the front surface; the front passivated contact layer is deposited to form n-type doped amorphous/polycrystalline silicon over the silicon oxide layer.

An intermediate layer unit is prepared on the bottom cell unit, in particular by a deposition method. The method includes PVD physical vapor deposition or RPD reactive plasma deposition.

The textured surface is prepared on the front and the back sides of the monocrystalline silicon wafer by using an alkaline solution, and the structure of the textured surface is pyramid-shaped.

After performing etching and polishing on the rear textured surface of the monocrystalline silicon wafer, the method specifically further includes the following steps:

depositing aluminum oxide and silicon nitride on the rear textured surface of the monocrystalline silicon wafer;

carrying out laser grooving on the rear textured surface of the monocrystalline silicon wafer, and locally melting the aluminum oxide and silicon nitride layer;

printing aluminum paste and silver paste on the rear textured surface of the monocrystalline silicon wafer, and performing sintering;

cleaning and oxidizing the front textured surface of the monocrystalline silicon wafer to form a thin oxide layer on the front surface, a thickness of the thin oxide layer being 1-10 nm; and

depositing a passivated contact layer on the first silicon oxide layer, wherein the passivated contact layer is n-type doped amorphous or polycrystalline silicon.

In yet another aspect, the invention provides a laminated cell structure including a top cell unit, a bottom cell unit, and an intermediate layer located between the top cell unit and the bottom cell unit; the intermediate layer is configured as a tunnel junction composed of a p⁺/n⁺ double-layer silicon thin film;

the top cell unit includes an electron transport layer, a perovskite photosensitive layer, a hole transport layer sequentially laminated in a direction from the distance to the vicinity with respect to the intermediate layer, and a front electrode provided on the electron transport layer;

the bottom cell unit is a PERC solar cell.

As a further improvement of the implementation mode of the invention, the top cell unit further includes an antireflective layer, a transparent conductive layer, and a passivated protective film layer sequentially laminated in the direction from the distance to the vicinity with respect to the electron transport layer.

As a further improvement of the implementation of the invention, the bottom cell unit comprises a passivated contact layer, a silicon oxide layer, a monocrystalline silicon base layer, a rear passivated film layer, a rear protective layer, and a rear electrode sequentially laminated in a direction from the vicinity to the distance with respect to the intermediate layer.

As a further improvement of the implementation of the invention, the hole transport layer is a nickel oxide layer; and the electron transport layer is a zinc oxide layer or a lithium fluoride layer.

As a further improvement of the implementation of the invention, the passivated contact layer of the bottom cell unit is an n-type silicon thin film passivated contact layer configured as a textured structure.

As a further improvement of the implementation of the invention, the passivated contact layer is formed with an inscribed electrode on its surface facing the intermediate layer.

In yet another aspect, the invention provides a preparation method for the laminated cell structure, which includes the following steps:

providing a PERC solar cell;

forming an intermediate layer on the PERC solar cell; the intermediate layer being configured as a tunnel junction composed of a p⁺/n⁺ double-layer silicon thin film;

forming a top cell unit with a perovskite photosensitive layer on the intermediate layer;

and the top cell unit including an electron transport layer, a perovskite photosensitive layer, a hole transport layer sequentially laminated in a direction from the distance to the vicinity with respect to the intermediate layer, and a front electrode deposited on the electron transport layer.

As a further improvement of the implementation of the invention, the intermediate layer formed on the PERC solar cell is specifically formed by means of deposition method, including PVD physical vapor deposition or RPD reactive plasma deposition.

As a further improvement of the implementation of the invention, the front and back sides of the intermediate layer are textured to produce a pyramid-shaped textured structure.

As a further improvement of the implementation of the invention, providing the PERC solar cell includes the following specific steps:

S101, texturing the front and the back sides of the monocrystalline silicon wafer by using an alkaline solution to prepare a textured surface structure with the edge length of 1-10 μm of a pyramid base;

S102, performing phosphorus diffusion to form n-type silicon layers on the front side of the monocrystalline silicon wafer to form an emitter region with an n-type front side;

S103, etching and polishing the rear side of the monocrystalline silicon wafer by using an acid or alkali solution to remove a rear diffusion layer and a side face conductive channel;

S104, performing thermal oxidation on the monocrystalline silicon wafer in an oxidation furnace to form a silicon oxide layer on the front and the back sides;

S105, performing oxidizing and annealing on the rear-side, and depositing an aluminum oxide passivated layer on the rear-side;

S106, depositing a protective layer on the rear-side after annealing;

and S107, preparing a rear electrode.

As a further improvement of the implementation of the invention, after etching and polishing the rear-side, the method specifically includes the following steps:

depositing aluminum oxide and silicon nitride on the rear-side; carrying out laser grooving on the rear-side, and locally melting the aluminum oxide and silicon nitride layer; printing the rear-side with aluminum paste and silver paste, and sintering;

and cleaning the front side; oxidizing the front side, and forming a thin oxide layer of 1-10 nm on the front surface; depositing the front passivated contact layer to form n-type doped amorphous/polycrystalline silicon over the silicon oxide layer.

As a further improvement of the implementation of the invention, the antireflective layer is one or more of silicon oxide, silicon nitride, silicon oxynitride, and magnesium fluoride.

As a further improvement of the implementation of the invention, the rear passivated film layer includes an aluminum oxide layer and a silicon oxide layer arranged in a laminating manner.

As a further improvement of the implementation of the invention, the protective layer is silicon nitride or silicon oxynitride.

According to the invention, the alkaline made texture with a pyramid textured surface structure is adopted on the surface of the bottom cell, so that the problem of poor planar light trapping effect is overcome, and the optical performance of the cell can be greatly improved; further, the industry can be updated without any interruption, and the low-cost mass production of the cell with a laminated structure can be realized. Besides, when the perovskite cell and the crystalline silicon solar cell constitute the 2T laminated solar cell, the tunnel junction is adopted as the linking layer of the two cells, and the technical defects that special deposition equipment is needed or the perovskite cell prepared on the TCO is uneven and poor in performance in the prior art are overcome.

### BRIEF DESCRIPTION OF THE DRAWINGS

In order to explain the technical solutions in the embodiments of the invention more clearly, the following will briefly introduce the drawings needed in the description of the embodiments. Apparently, the drawings in the following description are only some embodiments of the invention. For those of ordinary skills in the art, other drawings can be obtained based on these drawings without creative efforts.

FIG. 1 is a schematic view of a laminated cell structure provided by an embodiment of the invention;

FIG. 2 is a flowchart of a laminated cell structure and a preparation method thereof provided by an embodiment of the invention.

The reference signs in the drawings are indicated as: 1-top cell unit; 11-electron transport layer; 12-perovskite photosensitive layer; 13-hole transport layer; 14-antireflective layer; 15-transparent conductive layer; 16-passivated protective film layer; 17-front electrode; 2-bottom cell unit; 21-passivated contact layer; 22-silicon oxide layer; 23-monocrystalline silicon base layer; 24-rear passivated film layer; 25-rear protective layer; 26-rear electrode; 3-intermediate layer unit; 31-p⁺ silicon thin film layer; and 32-n⁺ silicon thin film layer.

### DESCRIPTION OF THE EMBODIMENTS

In order to make the object, solutions and advantages of the invention clearer, the solutions in the embodiments of the invention will be described clearly and completely in conjunction with the accompanying drawings in the embodiments of the invention. Apparently, the described embodiments are only part of the embodiments of the invention, but not all of the embodiments. Based on the embodiments of the invention, any other embodiment obtained by a person of ordinary skills in the art without involving any creative effort are encompassed within the scope of the invention.

The application provides a laminated cell structure including a top cell unit 1, a bottom cell unit 2, and an intermediate layer unit 3 arranged between the top cell unit 1 and the bottom cell unit 2.

The top cell unit 1 includes an electron transport layer 11, a perovskite photosensitive layer 12, a hole transport layer 13, and a front electrode 17.

The electron transport layer 11, the perovskite photosensitive layer 12, and the hole transport layer 13 are sequentially laminated from the distance to the vicinity with respect to the intermediate layer unit 3, and the hole transport layer 13 is connected with the intermediate layer unit 3; the front electrode 17 is arranged on the electron transport layer 11.

The bottom cell unit 2 includes a passivated contact layer 21, a silicon oxide layer 22, a monocrystalline silicon base layer 23, a rear passivated film layer 24, a rear protective layer 25, and a rear electrode 26 which are sequentially laminated in a direction from the vicinity to the distance with respect to the intermediate layer.

The passivated contact layer 21, the silicon oxide layer 22, the monocrystalline silicon base layer 23, the rear passivated film layer 24, and the rear protective layer 25 are sequentially laminated in the direction from the vicinity to the distance with respect to the intermediate layer unit 3. The passivated contact layer 21 is connected with the intermediate layer unit 3; the rear electrode 26 is arranged on the rear protective layer 25.

The intermediate layer unit 3 includes a p⁺ silicon thin film layer 31 and an n⁺ silicon thin film layer 32, and is configured as a tunnel junction composed of the p⁺ silicon thin film layer 31 and the n⁺ silicon thin film layer 32.

In another implementation mode, the top cell unit 1 further includes an antireflective layer 14, a transparent conductive layer 15, and a passivated protective film layer 16 arranged on the electron transport layer 11, and the antireflective layer 14, the transparent conductive layer 15, and the passivated protective film layer 16 are sequentially laminated in the direction from the distance to the vicinity with respect to the electron transport layer 11.

In another implementation mode, the hole transport layer 13 is a nickel oxide layer; the electron transport layer 11 is a zinc oxide layer or a lithium fluoride layer.

In another implementation mode, the passivated contact layer 21 of the bottom cell unit 2 is an n-type silicon thin film passivated contact layer configured as a textured structure.

In another implementation mode, the passivated contact layer 21 is formed with an inscribed electrode on its surface facing the intermediate layer unit 3.

The application also provides an embodiment of a preparation method for a cell, which corresponds to the embodiment of the cell structure of the application. As shown in FIG. x, an embodiment of the preparation method may include the following steps:

S1: preparing a bottom cell unit;

S2: preparing an intermediate layer unit on the bottom cell unit; the intermediate layer unit being configured as a tunnel junction composed of a p⁺ silicon thin film layer and an n⁺ silicon thin film layer;

and S3: preparing a top cell unit with a perovskite photosensitive layer on the intermediate layer unit.

The preparation of the bottom cell unit may include the following steps:

preparing a textured surface on the front and back sides of the monocrystalline silicon wafer by using an alkaline solution;

respectively forming a first silicon oxide layer and a second silicon oxide layer on the front textured surface and the back textured surface of the monocrystalline silicon wafer;

oxidizing and annealing the second silicon oxide layer, and depositing aluminum oxide on the second silicon oxide layer to form a rear passivated film layer;

depositing a rear protective layer on the rear passivated film layer, and

arranging a rear electrode on the rear protective layer;

depositing a passivated contact layer on the first silicon oxide layer;

respectively forming a first silicon oxide layer and a second silicon oxide layer on the front textured surface and the back textured surface of the monocrystalline silicon wafer specifically comprises the following steps:

performing phosphorus diffusion on the front textured surface of the monocrystalline silicon wafer to obtain a front textured surface formed with an n-type emitter region;

etching and polishing the rear textured surface of the monocrystalline silicon wafer to obtain a rear textured surface with the rear diffusion layer and the side face conductive channel removed;

and performing thermal oxidation on the monocrystalline silicon wafer in an oxidation furnace, and respectively forming a first silicon oxide layer and a second silicon oxide layer on the front textured surface and the back textured surface of the monocrystalline silicon wafer.

The front face is cleaned; the front face is oxidized, and a thin oxide layer of 1-10 nm is formed on the front surface; the front passivated contact layer is deposited to form n-type doped amorphous/polycrystalline silicon over the silicon oxide layer.

An intermediate layer unit is prepared on the bottom cell unit, in particular by a deposition method. The method includes PVD physical vapor deposition or RPD reactive plasma deposition.

The textured surface is prepared on the front and back sides of the monocrystalline silicon wafer by using an alkaline solution, and the structure of the textured surface is pyramid-shaped.

After performing etching and polishing on the rear textured surface of the monocrystalline silicon wafer, the method specifically further includes the following steps:

depositing aluminum oxide and silicon nitride on the rear textured surface of the monocrystalline silicon wafer;

carrying out laser grooving on the rear textured surface of the monocrystalline silicon wafer, and locally melting the aluminum oxide and silicon nitride layers;

printing aluminum paste and silver paste on the rear textured surface of the monocrystalline silicon wafer, and performing sintering;

cleaning and oxidizing the front textured surface of the monocrystalline silicon wafer to form a thin oxide layer on the front surface, wherein the thickness of the thin oxide layer is 1-10 nm; and

depositing a passivated contact layer on the first silicon oxide layer, wherein the passivated contact layer is n-type doped amorphous or polycrystalline silicon.

The solutions of the application are further described below with reference to some examples.

### Example 1

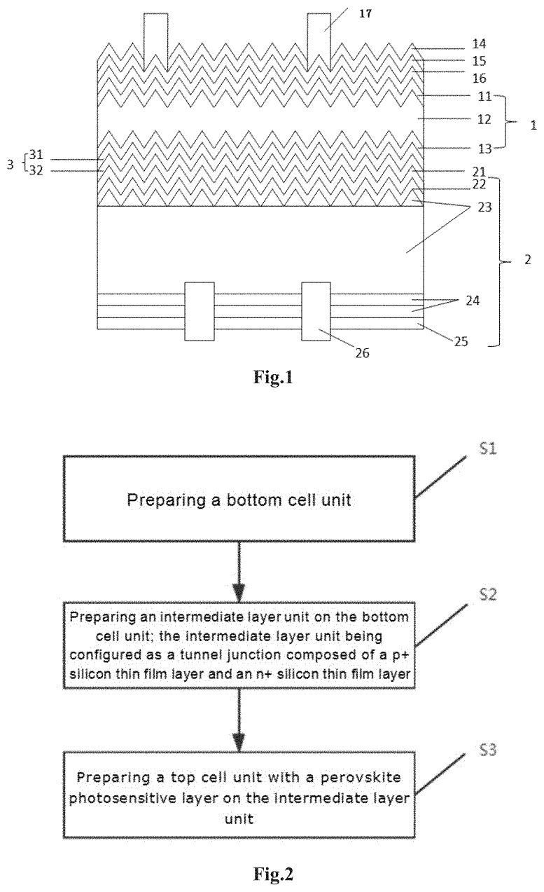

The example of the invention provides a laminated cell structure which, as shown in FIG. 1, includes a top cell unit 1, a bottom cell unit 2, and an intermediate layer unit 3 between the top cell unit 1 and the bottom cell unit 2; the intermediate layer unit 3 is configured as a tunnel junction composed of a p⁺/n⁺ double-layer silicon thin film, specifically including a p⁺ silicon thin film layer 31 and an n⁺ silicon thin film layer 32;

the top cell unit 1 includes an electron transport layer 11, a perovskite photosensitive layer 12, a hole transport layer 13 sequentially laminated in a direction from the distance to the vicinity with respect to the intermediate layer unit 3, and a front electrode is provided on the electron transport layer 11;

the bottom cell unit 2 is a PERC solar cell.

In the embodiment of the invention, the top cell unit 1 further includes an antireflective layer 14, a transparent conductive layer 15, and a passivated protective film layer 16 sequentially laminated in the direction from the distance to the vicinity with respect to the electron transport layer. The front electrode 17 can be one or more of gold, silver, copper and aluminum; the antireflective layer 14 can be one or more of silicon oxide, silicon nitride, silicon oxynitride and MgF; the transparent conductive layer 15 can be one or more of zinc oxide, tin oxide, molybdenum oxide and indium oxide; the passivated protective film layer 16 is a C60 material; the electron transport layer 11 is a LiF layer; the hole transport layer 13 is Spiro-MeOTAD.

Further, the bottom cell unit 2 includes a passivated contact layer 21, a silicon oxide layer 22, a monocrystalline silicon base layer 23, a rear passivated film layer 24, a rear protective layer 25, and a rear electrode 26 sequentially laminated in a direction from the vicinity to the distance with respect to the intermediate layer unit 3.

The hole transport layer 13 is a nickel oxide layer; the electron transport layer 11 is a lithium fluoride layer, and optionally a zinc oxide layer. The passivated contact layer 21 of the bottom cell unit 2 is an n-type silicon thin film passivated contact layer configured as a textured structure. The passivated contact layer 21 is formed with an inscribed electrode on its surface facing the intermediate layer unit 3.

The rear passivated film layer 24 includes an aluminum oxide layer and a silicon oxide layer, and a p⁺⁺ local area rear field layer is further provided on the lower surface of the p type monocrystalline silicon base layer. The rear protective layer 25 is a silicon nitride layer; the rear electrode 26 may be one or more of gold, silver, copper, and aluminum.

### Embodiment 2

The embodiment of the invention provides a preparation method for the laminated cell structure, which includes the following steps:

providing a PERC solar cell;

forming an intermediate layer on the PERC solar cell; the intermediate layer being configured as a tunnel junction composed of a p⁺/n⁺ double-layer silicon thin film;

forming a top cell unit with a perovskite photosensitive layer on the intermediate layer;

and the top cell unit including an electron transport layer, a perovskite photosensitive layer, a hole transport layer sequentially laminated in a direction from the distance to the vicinity with respect to the intermediate layer, and a front electrode deposited on the electron transport layer.

As a further improvement of the implementation of the invention, the intermediate layer formed on the PERC solar cell is specifically formed by means of a deposition method, including PVD physical vapor deposition or RPD reactive plasma deposition.

As a further improvement of the implementation of the invention, the front and back sides of the intermediate layer are textured to produce a pyramid-shaped textured structure.

As a further improvement of the implementation of the invention, providing the PERC solar cell includes the following specific steps:

S101, texturing the front and back sides of the monocrystalline silicon wafer by using an alkaline solution to prepare a textured surface structure with the edge length of 1-10 μm of a pyramid base;

S102, performing phosphorus diffusion on the front side of the monocrystalline silicon wafer to form a front n-type emitter region;

S103, etching and polishing the rear-side of the monocrystalline silicon wafer by using an acid or alkali solution to remove a rear diffusion layer and a side conductive channel;

S104, performing thermal oxidation on the monocrystalline silicon wafer in an oxidation furnace to form a silicon oxide layer on the front and back sides;

S105, performing oxidizing and annealing on the rear-side, and depositing an aluminum oxide passivated layer on the rear-side;

S106, depositing a protective layer on the rear-side after annealing;

and S107, preparing a rear electrode.

As a further improvement of the implementation of the invention, after etching and polishing the rear-side, the method specifically includes the following steps:

depositing aluminum oxide and silicon nitride on the rear-side; carrying out laser grooving on the rear-side, and locally melting the aluminum oxide and silicon nitride layers; printing the rear-side with aluminum paste and silver paste, and sintering;

and cleaning the front side; oxidizing the front side, and forming a thin oxide layer of 1-10 nm on the front surface; depositing the front passivated contact layer to form n-type doped amorphous/polycrystalline silicon over the silicon oxide layer.

As a further improvement of the implementation of the invention, the antireflective layer is one or more of silicon oxide, silicon nitride, silicon oxynitride, and magnesium fluoride.

As a further improvement of the implementation of the invention, the rear passivated film layer includes an aluminum oxide layer and a silicon oxide layer arranged in a laminating manner.

The invention has the beneficial effects as follows:

1. according to the invention, the alkaline made texture with a pyramid textured surface structure is adopted on the surface of the bottom cell so that the problem of poor planar light trapping effect is overcome, and the optical performance of the cell can be greatly improved;

2. according to the invention, the bottom cell adopts the PERC cell, and it can upgrade the industry without interruptions, and realizes low-cost mass production of the cell with a laminated structure;

3. according to the invention, when the perovskite cell and the crystalline silicon solar cell compose the 2T laminated solar cell, the tunnel junction is adopted as the linking layer of the two cells, and the technical defects that special deposition equipment is needed or the perovskite cell prepared on the TCO is seriously uneven and poor in performance in the prior art are overcome.

All of the alternative technical solutions described above may be used in any combination to form alternative embodiments of the invention and will not be discussed in detail herein.

The above are only preferred embodiments of the invention and are not intended to limit the invention. Any modification, equivalent replacement, improvement, etc. made within the spirit and principle of the invention shall be encompassed in the scope of the invention.

What is claimed is:

1. A laminated cell structure, characterized by comprising a top cell unit (1), a bottom cell unit (2), and an intermediate layer unit (3) arranged between the top cell unit (1) and the bottom cell unit (2);
wherein the top cell unit (1) comprises an electron transport layer (11), a perovskite photosensitive layer (12), a hole transport layer (13), and a front electrode (17);
the electron transport layer (11), the perovskite photosensitive layer (12), and the hole transport layer (13) are sequentially laminated in a direction from the distance to the vicinity with respect to the intermediate layer unit (3), and the hole transport layer (13) is connected with the intermediate layer unit (3);
the front electrode (17) is arranged on the electron transport layer (11);
the bottom cell unit (2) comprises a passivated contact layer (21), a silicon oxide layer (22), a monocrystalline silicon base layer (23), a rear passivated film layer (24), a rear protective layer (25), and a rear electrode (26) sequentially laminated in a direction from the vicinity to the distance with respect to the intermediate layer unit (3);
the passivated contact layer (21), the silicon oxide layer (22), the monocrystalline silicon base layer (23), the rear passivated film layer (24), and the rear protective layer (25) are sequentially laminated in the direction from the vicinity to the distance with respect to the intermediate layer unit (3), and the passivated contact layer (21) is connected with the intermediate layer unit (3);
the rear electrode (26) is arranged on the rear protective layer (25);
the intermediate layer unit (3) comprises a p⁺ silicon thin film layer (31) and an n⁺ silicon thin film layer (32), and is configured as a tunnel junction composed of the p⁺ silicon thin film layer (31) and the n⁺ silicon thin film layer (32).

2. The laminated cell structure according to claim 1, characterized in that the top cell unit (1) further comprises an antireflective layer (14), a transparent conductive layer (15), and a passivated protective film layer (16) arranged on the electron transport layer (11), and the antireflective layer (14), and the transparent conductive layer (15) and the passivated protective film layer (16) are sequentially laminated in a direction from the distance to the vicinity with respect to the electron transport layer (11).

3. The laminated cell structure according to claim 1, characterized in that the hole transport layer (13) is a nickel oxide layer and the electron transport layer (11) is a zinc oxide layer or a lithium fluoride layer.

4. The laminated cell structure according to claim 1, characterized in that the passivated contact layer (21) is an n-type silicon thin film passivated contact layer configured as a textured surface structure.

5. The laminated cell structure according to claim 1, characterized in that the passivated contact layer (21) is formed with an inscribed electrode on its surface facing the intermediate layer unit (3).

6. A preparation method for a laminated cell structure, characterized by comprising the following steps:
preparing a bottom cell unit;
preparing an intermediate layer unit on the bottom cell unit; the intermediate layer unit being configured as a tunnel junction composed of a p⁺ silicon thin film layer and an n⁺ silicon thin film layer; and
preparing a top cell unit with a perovskite photosensitive layer on the intermediate layer unit.

7. The preparation method for a laminated cell structure according to claim 6, characterized in that the preparing a bottom cell unit specifically comprises the following steps:
preparing a textured surface on a front and a back sides of a monocrystalline silicon wafer by using an alkaline solution;
respectively forming a first silicon oxide layer and a second silicon oxide layer on the front textured surface and the back textured surface of the monocrystalline silicon wafer;
oxidizing and annealing the second silicon oxide layer, and depositing aluminum oxide on the second silicon oxide layer to form a rear passivated film layer;
depositing a rear protective layer on the rear passivated film layer, and
arranging a rear electrode on the rear protective layer; and
depositing a passivated contact layer on the first silicon oxide layer.

8. The preparation method for a laminated cell structure according to claim 7, characterized in that the respectively forming a first silicon oxide layer and a second silicon oxide layer on the front textured surface and the back textured surface of the monocrystalline silicon wafer specifically comprises the following steps:
performing phosphorus diffusion on a front textured surface of the monocrystalline silicon wafer to obtain a front textured surface formed with an n-type emitter region;
etching and polishing a rear textured surface of the monocrystalline silicon wafer to obtain a rear textured surface with a rear diffusion layer and a side conductive channel removed; and
performing thermal oxidation on the monocrystalline silicon wafer in an oxidation furnace, and respectively forming a first silicon oxide layer and a second silicon oxide layer on the front textured surface and the back textured surface of the monocrystalline silicon wafer.

9. The preparation method for a laminated cell structure according to claim 7, characterized in that the preparing an intermediate layer unit on the bottom cell unit is specifically prepared by means of the deposition method, which comprises PVD physical vapor deposition or RPD reactive plasma deposition.

10. The preparation method for a laminated cell structure according to claim 8, characterized in that a textured surface is prepared on the front and back sides of the monocrystalline silicon wafer by using an alkaline solution, the structure of the textured surface being pyramid-shaped.

11. The preparation method for a laminated cell structure according to claim 9, characterized in that after etching and polishing the rear textured surface of the monocrystalline silicon wafer, the method specifically further comprises the following steps:
depositing aluminum oxide and silicon nitride on the rear textured surface of the monocrystalline silicon wafer;
carrying out laser grooving on the rear textured surface of the monocrystalline silicon wafer, and locally melting the aluminum oxide and silicon nitride layers;
printing aluminum paste and silver paste on the rear textured surface of the monocrystalline silicon wafer, and performing sintering;
cleaning and oxidizing the front textured surface of the monocrystalline silicon wafer to form a thin oxide layer on the front surface, a thickness of the thin oxide layer being 1-10 nm; and
depositing a passivated contact layer on the first silicon oxide layer, wherein the passivated contact layer is n-type doped amorphous or polycrystalline silicon.
